(19) United States
(12) Patent Application Publication
(10) Pub. No.: US 2012/0018206 A1
(43) Pub. Date: Jan. 26, 2012

(54) SOLID ELECTROLYTIC CAPACITOR

(75) Inventors: Hidenori Suenaga, Tokyo (JP); Yoshihiro Takeda, Tokyo (JP); Miyuki Ujiie, Tokyo (JP); Katsunori Nogami, Tokyo (JP); Toshiyuki Murakami, Tokyo (JP); Hitoshi Aita, Tokyo (JP)

(73) Assignee: NIPPON CHEM-CON CORPORATION, TOKYO (JP)

(21) Appl. No.: 13/260,149

(22) PCT Filed: Mar. 30, 2010
(86) PCT No.: PCT/JP2010/055762

§ 371 Date: Sep. 23, 2011

(30) Foreign Application Priority Data
Mar. 31, 2009 (JP) 2009-088318
May 22, 2009 (JP) 2009-124737
Sep. 30, 2009 (JP) 2009-228751

(51) Int. Cl. H05K 1/18; H01G 9/04

(52) U.S. Cl. 174/260; 361/528

(57) ABSTRACT

There is provided a capacitor that has excellent transient response characteristics, can be used as a distributed constant type noise filter, and can be used as a composite component having two functions of a capacitor and a distributed constant type noise filter through further reduction of an ESL of a solid electrolytic capacitor with a solid electrolytic capacitor of which capacitance is easily increased.

There are prepared two capacitor element pieces 121 where both ends of an anode body of each of the capacitor element pieces form anode lead-out portions 122 and 122 and both surfaces of a middle portion of the anode body form cathode lead-out portions 123. The two capacitor element pieces 121 and 121 are stacked so that the cathode lead-out portions 123 and 123 overlap with each other and the anode lead-out portions 122 and 122 are substantially orthogonal to each other. Accordingly, a capacitor element 120 is formed. As a mounting board 141, there is prepared a mounting board 141 that includes conductors 144 and 145 and anode terminal portions 142 and a cathode terminal portion 143. The conductors 144 and 145 correspond to anode lead-out portions 122 and 122 and a cathode lead-out portion 123 of the capacitor element, and are formed on an element mounting surface of the mounting board. The anode terminal portions 142 and the cathode terminal portion 143 are formed on a mounting surface of the mounting board. The conductors 144 and 145 are connected to the anode terminal portions 142 and the cathode terminal portion 143. The capacitor element 120 is mounted on the mounting board 141, so that a solid electrolytic capacitor is formed.

### TECHNICAL FIELD

The present invention relates to a solid electrolytic capacitor, and more particularly, to a solid electrolytic capacitor of which equivalent series inductance as an electric property is low and transient response characteristics are excellent or a solid electrolytic capacitor that functions as a distributed constant type noise filter.

### BACKGROUND ART

As the frequency of an electronic device has increased, a capacitor of which impedance characteristics in a high frequency area are excellent as compared to the related art has been demanded as a capacitor that is one of electronic components. Various solid electrolytic capacitors, which use a conductive polymer having high electrical conductivity in a solid electrolyte, are being examined in order to meet this demand.

Further, in recent years, there has been a strong demand for a size reduction and large capacity for solid electrolytic capacitors that are disposed around LSIs such as CPUs typified by computers, LSIs for image processing of televisions, memories exchanging data with these LSIs, and the like and are used to supply power to these devices. Furthermore, not only a low ESR (equivalent series resistance) according to high frequency but also a low ESL (equivalent series inductance) excellent in noise removal or transient response characteristics is strongly demanded. Accordingly, various examinations are being performed to meet this demand.

A solid electrolytic capacitor shown in FIG. 13 is known as a capacitor, for example, a solid electrolytic capacitor that uses a conductive polymer as a solid electrolyte, that is, a cathode layer. FIG. 13 is a cross-sectional view of a solid electrolytic capacitor in the related art. The solid electrolytic capacitor is formed as follows: After dielectric layers formed of an oxide film are formed on an anode body 304 made of valve metal, solid electrolyte layers (cathode layer) 305 formed of a conductive polymer are formed on the dielectric layers, a graphite layer 306 is further formed around the solid electrolyte layers, and a cathode layer formed of a silver paste layer 307 is sequentially formed. Then, an anode lead 309 is connected to the other end portion of the anode body 304, a cathode lead 310 is connected to the lower surface of the silver paste layer 307 and led to the outside, and molding is performed with a packaging resin 308. Meanwhile, this solid electrolytic capacitor is disclosed in Patent Document 7.

In general, as a method of making low ESL, there are known, a first method of extremely shortening the length of a current path; a second method of canceling a magnetic field, which is formed by a current path, by a magnetic field formed by another current path; and a third method of making effective ESL be 1/n by dividing a current path into n current paths.

For example, an invention disclosed in JP-A-2000-311832 employs the first and third methods, an invention disclosed in JP-A-06-267802 employs the second and third methods, and each of inventions disclosed in JP-A-06-267801, JP-A-11-288846, and Japanese Patent No. 4208831 employs the third method.

Further, a three-terminal capacitor type distributed constant type noise filter is disclosed in JP-A-2002-164760 as a distributed constant type noise filter that uses a conductive polymer as an electrolyte. The three-terminal capacitor type distributed constant type noise filter includes a distributed constant circuit forming portion where a plate formed of flat plate-shaped valve action metal is interposed between oxide films formed of two flat plate-shaped dielectrics. The three-terminal capacitor type distributed constant type noise filter includes a cathode terminal electrically conducted to the distributed constant circuit forming portion and anode terminals where a part of a plate made of valve action metal is connected to anode lead-out portions protruding from an oxide film made of a dielectric.

FIG. 14 is a cross-sectional view of a distributed constant type noise filter in the related art. The distributed constant type noise filter is formed as follows: A cathode is formed by sequentially forming a solid electrolyte (cathode layer) 405 made of a conductive polymer, a graphite layer 406, and a silver paste layer 407 on the surface of a central portion of a dielectric layer that is formed on an anode body 404 made of valve metal; and both end portions of the anode body 404 are used as a pair of anodes. Anode leads 409 are connected to both ends of the anode body, a cathode lead 410 is connected to a silver paste layer 407 formed at the center, and molding is performed with a packaging resin 408. This distributed constant type noise filter uses the structure of a three-terminal type solid electrolytic capacitor, and can also function as a solid electrolytic capacitor.

### CITATION LIST

### Patent Documents

[Patent Document 1] JP-A-2000-311832
[Patent Document 2] JP-A-06-267802
[Patent Document 3] JP-A-06-267801
[Patent Document 4] JP-A-11-288846
[Patent Document 5]: Japanese Patent No. 4208831
[Patent Document 6]: JP-A-2002-164760
[Patent Document 7]: JP-A-09-260215

### SUMMARY OF INVENTION

### Problem that the Invention is to Solve

In the capacitor disclosed in Patent Document 1 among the above-mentioned Patent Documents, it is possible to cope with high frequency by a thin-film capacitor. However, in order to increase capacitance, an area of the dielectric layer needs to be increased or dielectric layers need to be stacked. Further, a material used as the dielectric layer is perovskite composite oxide crystal containing Ba and Ti, and capacitance capable of being obtained is nanofarad (nF) order capacitance. There is a drawback that it is difficult to employ perovskite composite oxide crystal containing Ba and Ti when microfarad (μF) order capacitance is required.

Furthermore, in the solid electrolytic capacitor disclosed in Patent Documents 2 and 4, a current path is divided by making a solid electrolytic capacitor include four terminals, so that an ESL of the solid electrolytic capacitor becomes lower than that of a two-terminal type solid electrolytic capacitor in the related art.

However, since external anode terminals and external cathode terminals are mounted on a capacitor element in Patent Document 2, a current path in the solid electrolytic capacitor is not necessarily short.

Further, in a solid electrolytic capacitor disclosed in Patent Document 4, the respective terminals of anodes and cathodes are disposed on four side surfaces of the solid electrolytic capacitor and the four terminals are separated from each other. Accordingly, an effect for canceling an induced magnetic field cannot be expected.

In a solid electrolytic capacitor disclosed in Patent Document 3, a plurality of metal board parts positioned between capacitor parts is bent in a zigzag in directions in which metal board parts are opposite to each other and the capacitor parts are joined to each other and stacked, or metal boards positioned at both ends of capacitor parts of stacked solid capacitor unit plates are joined to each other so that all metal boards are connected in series. Accordingly, the bent metal board parts or the metal board parts, which are joined to each other, act as coils and a stacking type solid electrolytic capacitor is formed as a kind of filter circuit. Further, the stacking type solid electrolytic capacitor can be formed as an effective filter device through the combination of a capacitor and coils by covering the peripheral edges of the bent metal board parts or the metal board parts, which are joined to each other, with a magnetic material; and can be used as a noise absorbing device in a high frequency area. Since a lead frame is used as a current path between an external electrode and a capacitor element in the solid electrolytic capacitor, the current path in the solid electrolytic capacitor becomes redundant. For this reason, there is a problem in that an ESL reduction effect is not sufficient.

In a solid electrolytic capacitor disclosed in Patent Document 5, a pseudo five-terminal type solid electrolytic capacitor is employed and a current path of an anode is divided into four current paths, so that an effective ESL is reduced. However, since a lead frame is used as a current path between an external electrode and a capacitor element in the solid electrolytic capacitor, the current path in the solid electrolytic capacitor becomes redundant. For this reason, there is a problem in that an ESL reduction effect is not sufficient.

Since the solid electrolytic capacitors disclosed in the above-mentioned Patent Documents 1 to 5 have an ESL reduction effect larger than the ESL reduction effect of a two-terminal type capacitor known in the past as described above, the improvement of transient response characteristics of the solid electrolytic capacitors is expected. However, a sufficient effect is not necessarily obtained with respect to the demand for a low ESL that has been demanded in recent years.

Further, the solid electrolytic capacitors disclosed in the above-mentioned Patent Documents 1 to 5 are solid electrolytic capacitors that are aimed at reducing ESL, and are not aimed at functioning as transmission lines. Meanwhile, the solid electrolytic capacitors disclosed in Patent Documents 2, 3, and 5 are three-terminal type solid electrolytic capacitors, and it is considered that these solid electrolytic capacitors can be used as transmission lines. However, when being used as transmission lines, these solid electrolytic capacitors cannot be used as solid electrolytic capacitors coping with a transient response and are single-function solid electrolytic capacitors.

On the other hand, a distributed constant type noise filter disclosed in Patent Document 6 is known as a noise filter that employs the structure of a three-terminal type solid electrolytic capacitor and has a transmission line structure. However, since only a single function as a noise filter is provided in this structure, it is not possible to sufficiently meet the demand for transient response characteristics.

That is, a capacitor demands to be disposed near a CPU, and to have a function, which is excellent in terms of transient response characteristics and rapidly supplies power in regard to the instantaneous voltage drop of a CPU. A noise filter demands to also be disposed near a CPU, to remove high frequency noise of power supplied to the CPU, and to stabilize the operation of the CPU. For this reason, it is preferable that each of the capacitor and the noise filter be disposed near the CPU, but there is a limitation in disposing both the capacitor and the noise filter near the CPU due to the limitation of a mounting area.

Accordingly, a device, which has both the functions and can be used as a single capacitor, a single distributed constant type noise filter, or both a capacitor and a distributed constant type noise filter, is demanded.

The invention has been made in consideration of the above-mentioned problem, and an object of the invention is to provide a capacitor that has excellent transient response characteristics, can be used as a distributed constant type noise filter, and can be used as a composite component having two functions of a capacitor and a distributed constant type noise filter through further reduction of an ESL of a solid electrolytic capacitor with a solid electrolytic capacitor of which a capacitance is easily increased.

### Means for Solving the Problem

The above-mentioned object of the invention is achieved by the following structure.

(1) A solid electrolytic capacitor includes a capacitor element. The capacitor element includes capacitor element pieces. Both ends of an anode body of each of the capacitor element pieces form anode lead-out portions and both surfaces of a middle portion of the anode body form cathode lead-out portions. The capacitor element pieces are stacked so that the cathode lead-out portions overlap with each other and the anode lead-out portions are substantially orthogonal to each other.

(2) In the solid electrolytic capacitor according to (1), the cathode lead-out portions of the side surfaces of the stacked capacitor element pieces are connected to each other by a conductive material.

(3) A solid electrolytic capacitor includes a capacitor element where both ends of an anode body form anode lead-out portions and a dielectric layer, a solid electrolyte layer, and a cathode lead-out portion are sequentially formed on the anode body. A first cathode terminal portion is disposed at the center of a mounting surface facing a wiring board, anode terminal portions are disposed around the first cathode terminal portion, and second cathode terminal portions are disposed adjacent to the anode terminal portions.

(4) A solid electrolytic capacitor includes a capacitor element and a mounting board. In the capacitor element, both ends of an anode body form anode lead-out portions and a dielectric layer, a solid electrolyte layer, and a cathode lead-out portion are sequentially formed on the anode body. The mounting board includes a surface on which the capacitor element is mounted and a mounting surface facing a wiring board. Conductors, which correspond to the anode lead-out portions and the cathode lead-out portion of the capacitor element, respectively, are formed on the surface on which the capacitor element is mounted. Anode terminal portions and a cathode terminal portion are formed on the mounting surface facing the wiring board. The conductors penetrate the wiring board and are electrically connected to the anode terminal portions and the cathode terminal portion. A first cathode terminal portion is disposed at the center of the mounting surface of the mounting board. The anode terminal portions are disposed around the first cathode terminal portion, that is, on four sides of the mounting surface of the mounting board. Second cathode terminal portions are disposed at four corners of the mounting surface of the mounting board so as to be adjacent to the anode terminal portions.

(5) In the solid electrolytic capacitor according to (3) or (4), the first cathode terminal portion is formed at an area of which the size is substantially the same as the size of the cathode lead-out portion of the capacitor element and corresponds to an area larger than the anode terminal portions and the second cathode terminal portions.

(6) In the solid electrolytic capacitor according to any one of (3) to (5), the first cathode terminal portion is disposed at an area that is a central portion of the mounting surface of the mounting board and close to the respective anode terminal portions, and an insulating area is formed at a central portion of the mounting surface.

(7) A solid electrolytic capacitor includes a capacitor element and a quadrangular mounting board. A mounting surface, which is surface-mounted on a printed board, is formed on one surface of the mounting board, and an element mounting surface on which a capacitor element is mounted is formed on the other surface of the mounting board. The mounting board includes anode terminal portions, a cathode terminal portion, anode conductors, and a cathode conductor. The anode terminal portions are disposed at four corners of the mounting surface of the element mounting surface. The cathode terminal portion is disposed at a central portion of the element mounting surface. The anode conductors are electrically conducted to the anode terminal portions and disposed at four corners of the element mounting surface. The cathode conductor is electrically conducted to the cathode terminal portion and disposed at a central portion of the element mounting surface. The capacitor element includes a capacity forming portion, a cathode layer, and a cathode lead-out portion that are sequentially stacked on a central portion of a conductive body, and anode lead-out portions that are formed of four conductive bodies protruding from the periphery of the cathode lead-out portion. The anode lead-out portions of the capacitor element are connected to the anode conductors of the mounting board. The cathode lead-out portion of the capacitor element is connected to the cathode conductor. Transmission line structures are formed by conductive bodies of the capacitor element that are positioned at opposite corners of the mounting board.

(8) In the solid electrolytic capacitor according to (7), the capacitor element is formed of a rectangular conductive body, and the anode lead-out portions are formed by stacking a plurality of capacitor element pieces, each of which protrudes from both ends of the cathode lead-out portion, in a cross shape.

(9) In the solid electrolytic capacitor according to (7), the capacitor element is formed of a cross-shaped conductive body and the anode lead-out portions protrude from the periphery of the cathode lead-out portion.

### Advantageous Effects of Invention

According to the solid electrolytic capacitor of (1), a solid electrolytic capacitor uses a capacitor element. The capacitor element includes capacitor element pieces. Both ends of an anode body of each of the capacitor element pieces form anode lead-out portions and both surfaces of a middle portion of the anode body form cathode lead-out portions. The capacitor element pieces are stacked so that the cathode lead-out portions overlap with each other and the anode lead-out portions are substantially orthogonal to each other. Accordingly, the anode lead-out portions are formed at four positions, so that it is possible to divide a current path into four current paths and to make a practical ESL be 1/4.

Further, the anode terminal portions, which are disposed so as to face each other, are electrically connected to each other in the capacitor element piece and the solid electrolytic capacitor includes the cathode lead-out portion interposed between the anode lead-out portions. Accordingly, the solid electrolytic capacitor forms transmission line structures and can function as a three-terminal type noise filter. That is, when the solid electrolytic capacitor is mounted on a circuit board, an electrical signal, which is input from one of the anode terminal portions facing each other, is filtered and the electrical signal is output to the other anode terminal portion. Meanwhile, in the solid electrolytic capacitor of the invention, the stacked capacitor element pieces may be regarded as capacitors that are independent in an electrical circuit, respectively. Moreover, when the solid electrolytic capacitor is regarded as transmission line structures, interaction is small since the capacitor element pieces forming the transmission line structures cross each other. Accordingly, one pair of anode lead-out portions facing each other can be used as a noise filter and a pair of anode lead-out portions, which is disposed orthogonal to the anode lead-out portions functioning as the noise filter, can also be used as output terminals of a capacitor that copes with a transient response. Further, two capacitor element pieces can also be used as transmission lines, respectively.

According to the solid electrolytic capacitor of (2), the side surfaces of the cathode lead-out portions of the stacked capacitor element pieces are connected to each other by a conductive material. Accordingly, it is possible to reduce the internal resistance between the cathode lead-out portions of the stacked capacitor element. For this reason, since it is possible to rapidly supply electric charge, which is accumulated in a capacity forming portion of the stacked capacitor element, to any of the four anode lead-out portions, it is possible to obtain a solid electrolytic capacitor that is excellent in terms of transient response characteristics with respect to the whole of the solid electrolytic capacitor.

According to the solid electrolytic capacitor of (3), the solid electrolytic capacitor includes a capacitor element where both ends of an anode body form anode lead-out portions and a dielectric layer, a solid electrolyte layer, and a cathode lead-out portion are sequentially formed on the anode body. A first cathode terminal portion is disposed at the center of a mounting surface facing a wiring board, anode terminal portions are disposed around the first cathode terminal portion, and second cathode terminal portions are disposed adjacent to the anode terminal portions. Accordingly, first, it is possible to achieve the distances from the anode lead-out portion and the cathode lead-out portion of the capacitor element to the anode terminal portion and the cathode terminal portion of the mounting board, which are outlets of current, by a distance corresponding to only the thickness of the mounting board, and to shorten the current path. Second, since the anode terminal portion of the mounting board is disposed so as to be surrounded by the cathode terminal portions in three directions, an effect for canceling a magnetic field induced by the anodes and the cathode is large and it is possible to reduce the ESL of the solid electrolytic capacitor.

According to the solid electrolytic capacitor of (4), the mounting board of the solid electrolytic capacitor includes the anode conductors, the cathode conductor, the first cathode terminal portion, four anode terminal portions, and second cathode terminal portions. The anode conductors and the cathode conductor correspond to the anode lead-out portions and the cathode lead-out portion of the capacitor element, and are formed on the surface of the mounting board on which the capacitor element is mounted. The first cathode terminal portion is formed at the center of the mounting surface of the mounting board, and the four anode terminal portions are formed on four sides of the mounting surface of the mounting board so as to surround the outer periphery of the first cathode terminal portion. The second cathode terminal portions are formed at the four corners of the mounting surface of the mounting board and are electrically connected to the cathode lead-out portion of the capacitor element. Since the second cathode terminal portions are disposed adjacent to the anode terminal portions, the anode terminal portions are disposed so as to be surrounded by the first cathode terminal portion and the second cathode terminal portions in three directions. Further, the anode conductors, the anode terminal portions, the cathode conductor, and the cathode terminal portions are electrically connected to each other through conductors, which penetrate the mounting board. Accordingly, first, it is possible to achieve the distances from the anode lead-out portion and the cathode lead-out portion of the capacitor element to the anode terminal portion and the cathode terminal portion of the mounting board, which are outlets of current, by a distance corresponding to only the thickness of the mounting board, and to shorten the current path. Second, since the anode terminal portion of the mounting board is disposed so as to be surrounded by the cathode terminal portions in three directions, an effect for canceling a magnetic field induced by the anodes and the cathode is large. Third, it is possible to divide a current path into four current paths and to make a practical ESL be 1/4 by forming the anode terminal portions at four positions.

That is, it is possible to obtain a solid electrolytic capacitor of the invention that comprehensively improves an ESL reduction effect by using all of, a method of extremely shortening the length of a current path that is a first element technique for achieving low ESL; a method of canceling a magnetic field, which is formed by a current path, by a magnetic field formed by another current path that is a second element technique; and a method of making a practical ESL be 1/n by dividing a current path into n current paths that is a third element technique.

According to the solid electrolytic capacitor of (5), the first cathode terminal portion, which is disposed at the center of the mounting surface, is formed at an area of which the size is substantially the same as the size of the cathode lead-out portion of the capacitor element and corresponds to an area larger than the anode terminal portions and the second cathode terminal portions. Accordingly, the first cathode terminal portion can make the distance between the first cathode terminal portion and the cathode lead-out portion of the capacitor element be shortest, reduce ESL, increase the capacity of current that is output from the cathode lead-out portion of the capacitor element, and supply a large current during a transient response.

According to the solid electrolytic capacitor of (6), the first cathode terminal portion is disposed at an area that is a central portion of the mounting surface and close to the respective anode terminal portions, and an insulating area is formed at the central portion of the mounting surface. Accordingly, the current path of the first cathode terminal portion becomes narrow, so that current is concentrated. Further, since the first cathode terminal portion is disposed close to the anode terminal portions, it is possible to further improve an effect for canceling an induced magnetic field. That is, it is possible to obtain a solid electrolytic capacitor of which a comprehensive ESL reduction effect is further improved.

According to the solid electrolytic capacitor of (7), the anode terminal portions are led in four directions. Accordingly, the solid electrolytic capacitor functions as a five-terminal type capacitor where a cathode terminal portion is disposed at the central portion thereof. Moreover, the capacitor element includes a capacity forming portion, a cathode layer, and a cathode lead-out portion that are sequentially stacked on a central portion of a conductive body, and anode lead-out portions that are formed of four conductive bodies protruding from the periphery of the cathode lead-out portion. The anode terminal portions, which are positioned at opposite corners, form a transmission line structure by the conductive bodies. Further, since it is possible to make the dielectric layer and the cathode layer, which form the capacity forming portion of the capacitor element, function as a distributed constant circuit, it is possible to make the solid electrolytic capacitor function as a three-terminal type noise filter that uses a distributed constant circuit portion as a filter portion. That is, when the capacitor is mounted on a circuit board, an electrical signal, which is input from one of the anode terminal portions positioned at opposite corners and facing each other, is filtered at the distributed constant circuit portion and the electrical signal is output to the other anode terminal portion.

Further, the transmission line structures of the capacitor element are crossing structures. Accordingly, the crossing transmission line structures may be regarded as transmission lines that are independent in an electrical circuit, respectively. When a capacitor or the solid electrolytic capacitor of the invention is regarded as a distributed constant type noise filter, interaction is small since the transmission line structures are direct structures and the phases of induced magnetic fields generated from the respective transmission lines are different from each other.

Furthermore, the length of a transmission line on a predetermined quadrangular mounting surface may be longest in the case of the transmission line structure that is formed by the anode terminal portions disposed at opposite corners. For this reason, a distributed constant circuit portion, which is formed on the transmission line, can also be formed to be long. In general, in order to make the solid electrolytic capacitor of the invention function as a noise filter at high efficiency, it is preferable that the length of the distributed constant circuit portion be equal to or larger than 1/4λ when a wavelength of a noise wave is denoted by λ. For this reason, in order to make the solid electrolytic capacitor of the invention function as a noise filter that copes with broadband frequency, the longer distributed constant circuit portion is more suitable.

For this reason, in the solid electrolytic capacitor of (7), the length of the transmission line is longest among solid electrolytic capacitors having a predetermined mounting area and it is also possible to increase the length of the distributed constant circuit portion on the transmission line. Accordingly, it is possible to reduce the size of a noise filter that copes with a broadband noise.

Further, when being regarded as a solid electrolytic capacitor, the solid electrolytic capacitor of the invention is a five-terminal type solid electrolytic capacitor that includes a cathode terminal portion at the center thereof and four anode terminal portions around the cathode terminal portion. If the solid electrolytic capacitor of the invention is a five-terminal type solid electrolytic capacitor, it is possible to divide a current path into four current paths and to make a practical ESL of a solid electrolytic capacitor be 1/4.

Furthermore, in the solid electrolytic capacitor of (7), one of the crossing transmission line structures can be used as a solid electrolytic capacitor and the other thereof can be used as a distributed constant type noise filter. Accordingly, the solid electrolytic capacitor of (7) can be used as a composite electronic component.

### BRIEF DESCRIPTION OF DRAWINGS

FIG. 1 is a view showing the shape of a capacitor element piece that is used in a solid electrolytic capacitor according to a first embodiment of the invention, wherein FIGS. 1A and 1B are cross-sectional views and FIG. 1C is a top view.

FIG. 2 is a perspective view showing the shapes of a capacitor element piece and a capacitor element that are used in the solid electrolytic capacitor according to the first embodiment of the invention, wherein FIG. 2A shows the capacitor element piece and FIG. 2B shows the capacitor element.

FIG. 3 is a perspective view showing the shape of a mounting board that is used in the solid electrolytic capacitor according to the first embodiment of the invention, wherein FIG. 3A is a view showing a capacitor element mounting surface and FIG. 3B a view showing a mounting surface.

FIG. 4 is a cross-sectional view of the mounting board that is used in the solid electrolytic capacitor according to the first embodiment of the invention.

FIG. 5 is a view showing the solid electrolytic capacitor according to the first embodiment of the invention, wherein FIG. 5A is a top view and FIG. 5B is a cross-sectional view.

FIG. 6 is a view showing the shape of a mounting board that is used in a solid electrolytic capacitor according to a second embodiment of the invention, wherein FIG. 6A is a view showing a capacitor element mounting surface and FIG. 6B a view showing a mounting surface.

FIG. 7 is a cross-sectional view of the mounting board that is used in the solid electrolytic capacitor according to the second embodiment of the invention.

FIG. 8 is a view showing the solid electrolytic capacitor according to the second embodiment of the invention, wherein FIG. 8A is a top view and FIG. 8B is a cross-sectional view.

FIG. 9 is a view showing a modification of the mounting board that is used in the solid electrolytic capacitor according to the second embodiment of the invention, wherein FIG. 9A is a view showing a surface on which a capacitor element is mounted and FIG. 9B is a view showing a mounting surface.

FIG. 10 is a view showing a third embodiment of the invention, wherein FIG. 10A is a top view of a solid electrolytic capacitor and FIG. 10B is a cross-sectional view taken along a line A-A of FIG. 1A.

FIG. 11 is a view showing a modification of the third embodiment of the invention.

FIG. 12 is a view showing a mounting board that is used in a solid electrolytic capacitor according to a third embodiment of the invention, wherein FIG. 12A is a view showing an element mounting surface and FIG. 12B is a view showing a mounting surface.

FIG. 13 is a cross-sectional view showing an internal structure of a solid electrolytic capacitor in the related art.

FIG. 14 is a cross-sectional view showing an internal structure of a distributed constant type noise filter in the related art.

### DESCRIPTION OF EMBODIMENTS

Next, embodiments of the invention will be described in detail.

### First Embodiment

A capacitor element, which is used in a solid electrolytic capacitor according to a first embodiment of the invention, will be described first. The capacitor element, which is used in the solid electrolytic capacitor according to the first embodiment of the invention, has a structure where rectangular capacitor element pieces overlap with each other. Both ends of each of the capacitor element pieces are anode lead-out portions, and a middle portion between the anode lead-out portions of each of the capacitor element pieces is a cathode lead-out portion. The capacitor element pieces overlap with each other so that the cathode lead-out portions overlap with each other and the anode lead-out portions of the capacitor element pieces are orthogonal to each other. Accordingly, the capacitor element is formed so as to have a cathode lead-out portion at the central portion thereof and anode lead-out portions that are led out in four directions.

The capacitor element will be described in more detail below.

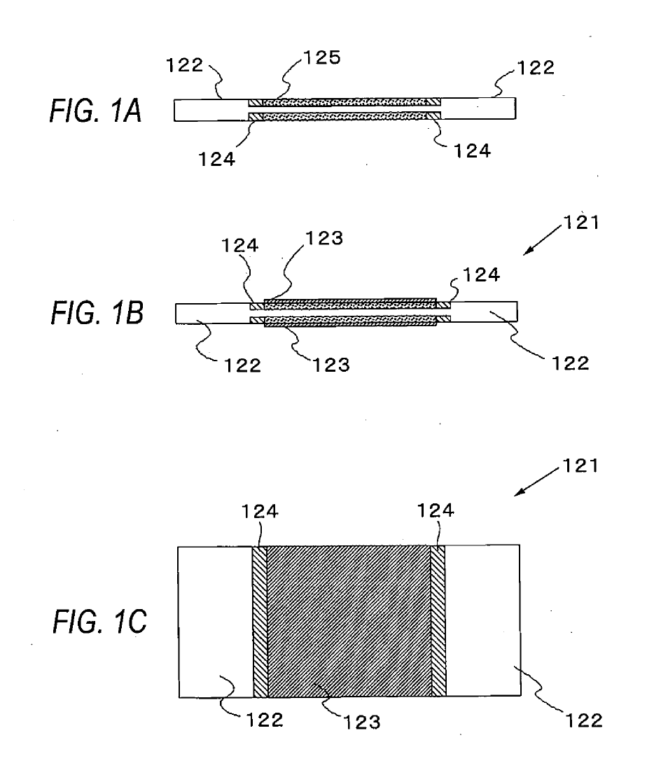

As shown in FIG. 1, in a capacitor element piece 121, a valve metal plate or valve metal foil (hereinafter, referred to as an anode body), which has a substantially rectangular shape and is made of aluminum or the like, is used, a middle portion of the anode body is enlarged by etching, and porous etching layers 125 are formed on both surfaces of the aluminum foil. In this case, an inner portion of the anode body is not etched, an aluminum bare metal remains at the inner portion of the anode body, and the aluminum bare metal forms a residual core layer (FIG. 1A). Further, a dielectric oxide film is formed on the surface of each of the etching layers 125 by anodizing. In this case, both end portions of the anode body are unetched portions, and form anode lead-out portions 122. After that, a dielectric oxide film is formed on the surface of each of the etching layers 125 by anodizing.

In more detail, etching is a process that dissolves both surface of the anode body by hydrochloric acid or the like and forms a porous etching layer. Resist protective films (not shown) are formed by applying a resist material to portions of an anode body, which is made of highly-pure aluminum foil and has a cross sectional size of, for example, 10 mm×5 mm and a thickness of 120 μm, between both ends of the anode body and positions corresponding to 1.5 mm from both ends of the anode body. After the resist protective film is formed, a middle portion of the anode body is etched at a depth of 40 μm from both surfaces of the anode body so that etching layers are formed. In this case, the thickness of the residual core layer is 40 μm.

Separating layers 124 are formed on the capacitor element piece, so that the anode lead-out portions 122 and the cathode lead-out portion 123 of the capacitor element piece 121 are divided from each other. An insulating resin is applied and penetrates the etching layers 125 after the completion of etching, and the separating layers 124 facilitate the insulation between the anode lead-out portions 122 and the etching layers 125. For example, each of the separating layers 124 may be formed at a portion between the unetched portion and a position corresponding to 0.5 mm from the unetched portion.

Further, the etched anode body is subjected to a chemical conversion treatment, which is performed by anodizing, so that a dielectric oxide film made of an aluminum oxide is formed. In the anodizing, a dielectric oxide film is formed by the application of a predetermined voltage while etched foil is immersed in an aqueous solution of boracic acid, adipic acid, or the like.

Furthermore, a solid electrolyte layer (not shown) is formed on the dielectric oxide film. The solid electrolyte layer is sequentially immersed in a solution that contains a polymerizable monomer which becomes a conductive polymer through polymerization and an oxidant solution, and is lifted from the respective solutions, thereby promoting a polymerization reaction. The solid electrolyte layer may be formed by a method of applying or ejecting a solution that contains a polymerizable monomer and an oxidant solution. Moreover, the solid electrolyte layer may be formed by a method of immersing the etched foil in a solution where a polymerizable monomer solution and an oxidant are mixed with each other, or applying the solution to the etched foil.

Further, the solid electrolyte layer may also be formed by a method using electropolymerization that is used in the field of a solid electrolytic capacitor, a method of applying and drying a conductive polymer solution, or the like. Furthermore, the solid electrolyte layer may be formed by the combination of these methods of forming a solid electrolyte layer.

Thiophene, pyrrole, and derivatives thereof may be preferably used as a polymerizable monomer that is used to form the solid electrolyte layer as described above. In particular, it is preferable that a monomer be thiophene or the derivatives thereof.

Materials having the following structure can be exemplified as the derivatives of thiophene. Since thiophene or the derivatives thereof have high conductivity and are particularly excellent in thermal stability as compared to polypyrrole or polyaniline, it is possible to obtain a solid electrolytic capacitor that has a low ESR and is excellent in terms of heat resistance.

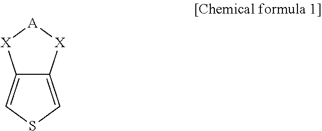

X is O or S.

When X is O, A is alkylene or polyoxyalkylene.

When at least one X is S, A is alkylene, polyoxyalkylene, substituted alkylene, or substituted polyoxyalkylene. Here, a substituent is an alkyl group, an alkenyl group, or an alkoxy group.

It is preferable that 3,4-ethylenedioxy thiophene among the derivatives of thiophene be used.

Ferric paratoluenesulfonate that is dissolved in ethanol, periodic acid, or an aqueous solution of iodic acid may be used as a softener that is used in the polymerization of a polymerizable monomer.

In addition, as shown in FIG. 1B, a graphite layer and a cathode layer formed of a silver paste layer are sequentially formed on the solid electrolyte layer of the capacitor element piece and form the cathode lead-out portion 123.

When the formation of the cathode lead-out portion 123 is completed, a resist protective film previously formed on the anode body is removed and aluminum of both end portions of the anode body is exposed and forms the anode lead-out portions 122. As a result, the capacitor element piece 121 is formed. The capacitor element piece 121 is formed so that each of the anode lead-out portions 122 and 122 formed at both ends of the capacitor element piece 121 has a length of 1.5 mm, each of the separating layers 124 has a length of 0.5 mm, the cathode lead-out portion 123 has a length of 6 mm, and the width of each of the anode lead-out portions, the separating layers, and the cathode lead-out portion is 5 mm.

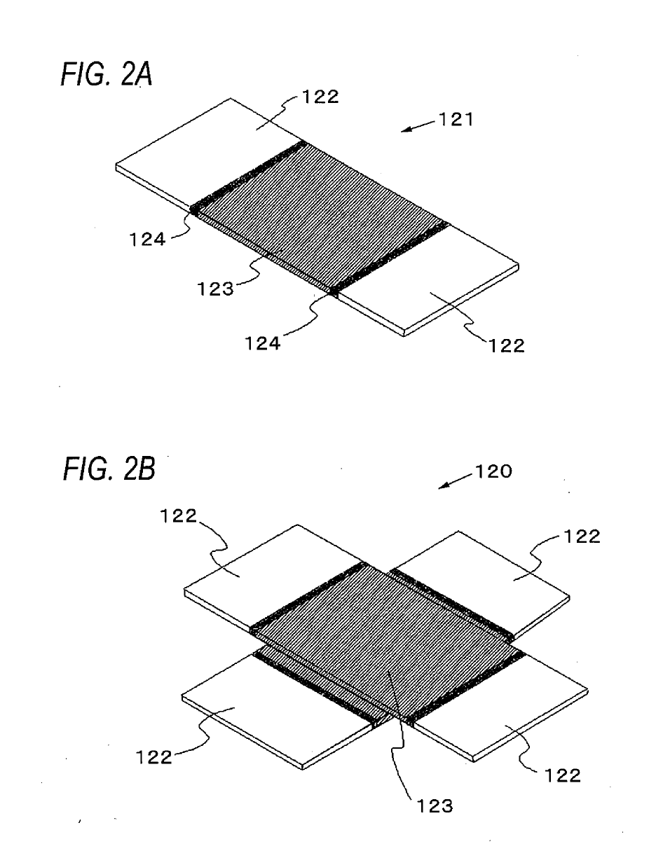

As shown in FIG. 2, the capacitor element pieces 121, which have been formed as described above, are stacked so that the cathode lead-out portions 123 overlap with each other and the anode lead-out portions 122 and 122 form a right angle therebetween. Accordingly, the capacitor element 120, which has a cross shape in a top view and in which the cathode lead-out portion 123 is formed at the central portion thereof and the anode lead-out portions 122 are radially disposed so as to protrude from the cathode lead-out portion 123 in four directions, is formed.

Since each of the cathode lead-out portions 123 of the capacitor element pieces 121 has a size of 5×6 mm and a rectangular shape, it is preferable that the capacitor element pieces be superimposed so that each of the end portions of the cathode lead-out portions 123 protrudes from the cathode lead-out portion by 0.5 mm when the capacitor element 120 is formed by stacking the capacitor element pieces 121. When the capacitor element pieces are superimposed so that each of the end portions of the cathode lead-out portions 123 protrudes from the cathode lead-out portion by 0.5 mm, the capacitor element 120 is formed to have a cross shape in a top view and the cathode lead-out portions 123 are disposed at the center of the capacitor element. However, the cathode lead-out portions 123 form a square shape which has a size of about 6×6 mm and of which four corner portions are cut out in a size of 0.5×0.5 mm. The cutout portions are filled with a conductive material to be described below, so that conductive paths making the cathode lead-out portions 123 and 123 of the upper and lower capacitor element pieces 121 and 121 be electrically conducted to each other are formed.

When a capacitor element is formed by stacking capacitor element pieces, each of which has the anode lead-out portions at both ends thereof and has the cathode lead-out portion at the middle portion thereof, in a cross shape in a top view as described above, it is possible to obtain the following properties.

(1) Since anode terminal portions are formed at four positions, it is possible to divide a current path into four current paths and to make a practical ESL be 1/4.

(2) Since anode terminal portions, which face each other, are electrically connected to each other in the capacitor element piece and the solid electrolytic capacitor includes the anode terminal portions 2 facing each other and a cathode terminal portion connected to the cathode lead-out portion, the solid electrolytic capacitor forms transmission line structures and can function as a triple-pole terminal type noise filter. When the solid electrolytic capacitor is mounted on a circuit board, an electrical signal, which is input from one of the anode terminal portions facing each other, is filtered and the electrical signal is output to the other anode terminal portion.

In addition, since the transmission line structures cross each other, interaction is small. Accordingly, one pair of anode terminal portions facing each other can be used as a noise filter and the other pair of anode terminal portions facing each other can be used as output terminals of a capacitor that copes with a transient response.

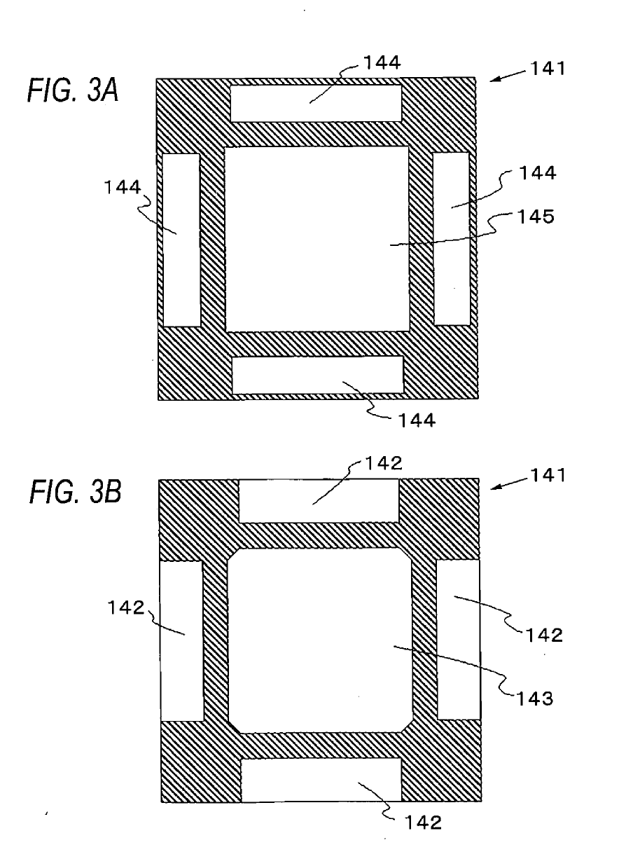

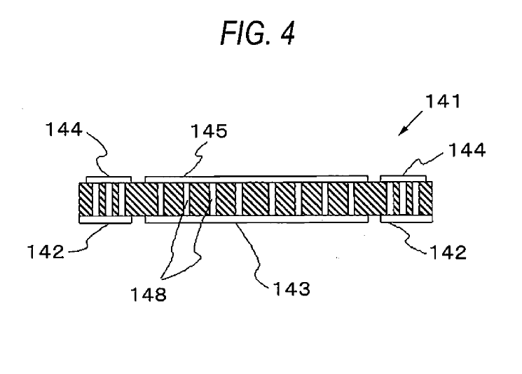

Next, a mounting board on which the capacitor element used in the first embodiment of the invention is mounted will be described with reference to FIGS. 3 and 4. A mounting board 141 uses an insulating board such as a rectangular glass epoxy board as a base, and includes anode terminal portions 142 and a cathode terminal portion 143 on the lower surface thereof. The mounting board includes anode conductors 144 and a cathode conductor 145 on the upper surface thereof. The anode conductors 144 and the cathode conductor 145 are connected to the anode lead-out portions and the cathode lead-out portion of the capacitor element, respectively. Further, the mounting board makes the anode conductors 144 and the anode terminal portions 142, which are formed on the upper and lower surfaces of the mounting board, respectively, be electrically conducted to each other and makes the cathode conductor 145 and the cathode terminal portion 143, which are formed on the upper and lower surfaces of the mounting board, respectively, be electrically conducted to each other.

A cathode conductor, which is joined to the cathode lead-out portion of the capacitor element, is formed at the central portion of a capacitor element mounting surface of the mounting board 141 in a square shape. Anode conductors 144 are disposed so as to surround the cathode conductor 145. Meanwhile, a cathode terminal portion 143 is formed at the central portion of a mounting surface of the mounting board 141, and four anode terminal portions 142 are disposed so as to surround the cathode terminal portion 143. The anode conductors 144, the anode terminal portions 142, the cathode conductor 145, and the cathode terminal portion 143, which are formed on both surfaces of the mounting board 141, are electrically joined to each other through electrodes 148, which penetrate the surface and back of the mounting board, such as via holes or through holes.

A glass epoxy board having a thickness of about 200 μm is preferably used as the glass epoxy board, which is the base of this mounting board, in terms of strength. However, a glass epoxy board having a thickness of about 80 μm may be used as the glass epoxy board that is the base of this mounting board. Further, it is sufficient that the electrodes and the conductors formed on the glass epoxy board can be soldered to a material having low electrical resistance, and it is preferable that copper or a conductor formed by plating nickel with gold be used as the conductor. The electrode and the conductor may be formed on one surface so as to have a thickness in the range of 3 to 5 μm. Further, the electrodes and the conductors that are formed on both surfaces of the mounting board 141, the through holes that electrically join the electrodes and the conductors, and the like may be formed by a method of forming a double-sided printed board that is frequently used as a printed board. In this case, the dispositions, the inner diameters, and the like of the through holes may be set arbitrarily.

In this mounting board, first, it is possible to achieve the distances from the anode lead-out portion and the cathode lead-out portion of the capacitor element to the anode terminal portion and the cathode terminal portion of the mounting board, which are outlets of current, by a distance corresponding to only the thickness of the mounting board, and to shorten the current path. In particular, it is preferable that the thickness of the mounting board be about 200μ, but a mounting board having a thickness of about 80 μm may be manufactured. Accordingly, it is possible to extremely shorten a distance from the cathode terminal portion to the cathode lead-out portion of the capacitor element as compared to a case where a capacitor element is mounted on a lead frame and is molded with a resin. Further, it is possible to divide a current path into four current paths and to make a practical ESL be 1/4 by forming the anode terminal portions at four positions. It is possible to reduce ESL of the solid electrolytic capacitor together with these two ESL reduction effects.

Next, a process for mounting the capacitor element on the mounting board will be described.

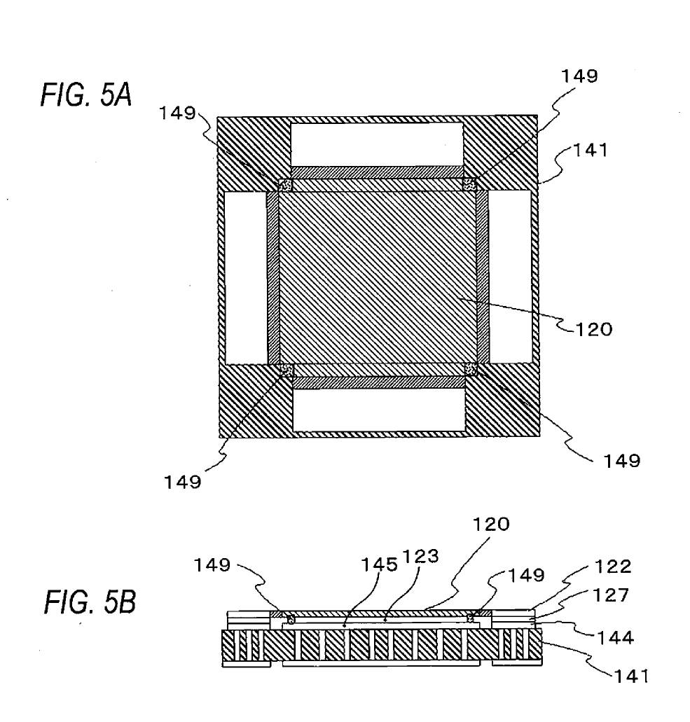

As shown in FIG. 5, the capacitor element 120 is mounted on the mounting board 141 and the cathode lead-out portion 123 of the capacitor element 120 and the cathode conductor 145 of the mounting board are joined to each other by a conductive adhesive material. Further, the anode lead-out portions 122 of the capacitor element 120 are connected to the anode conductors 144. In this case, the anode lead-out portion 122 of the capacitor element 120 is made of aluminum, has poor wettability between itself and a silver paste and the like, and may be difficult to adhere to the silver paste. In such a case, it is preferable that a connecting member 127 made of a copper material or the like be connected to the anode lead-out portion 122 of the capacitor element 120 by laser welding, ultrasonic welding, or the like and the connecting member 127 be joined to the anode conductor 144 of the mounting board 141 by a conductive adhesive material such as a silver paste.

In addition, the side surfaces of the cathode lead-out portions 123 of the stacked capacitor element pieces 121 of the capacitor element 120 are connected to each other by a conductive material 149 and are further connected to the cathode conductor 145. Accordingly, it is possible to reduce the internal resistance between the cathode lead-out portions 123 and 123 of the capacitor element pieces 121 and 121, which are stacked and disposed in a vertical direction, and a conductive path, which reaches the cathode conductor 145 of the mounting board 141, is formed. For this reason, since it is possible to rapidly supply electric charge, which is accumulated in a capacity forming portion of the stacked capacitor element, to any of the four anode terminal portions, it is possible to obtain a solid electrolytic capacitor that is excellent in terms of transient response characteristics with respect to the whole of the solid electrolytic capacitor.

Further, the number of capacitor elements mounted on the mounting board 141 is not limited to one. If large capacitance is required, it is possible to achieve the required capacitance by stacking more capacitor elements.

Furthermore, for the purpose of the mechanical protection of the capacitor element mounted on the mounting board or the blocking of the capacitor element from external air, packaging is performed by molding that is performed using a packaging resin. Meanwhile, packaging may be performed by attaching a case, which is made of a resin, to a board.

### Second Embodiment

Next, a second embodiment of the invention will be described. The same capacitor element pieces and capacitor element, which are formed by stacking the capacitor element pieces, as those of the first embodiment are used in the second embodiment.

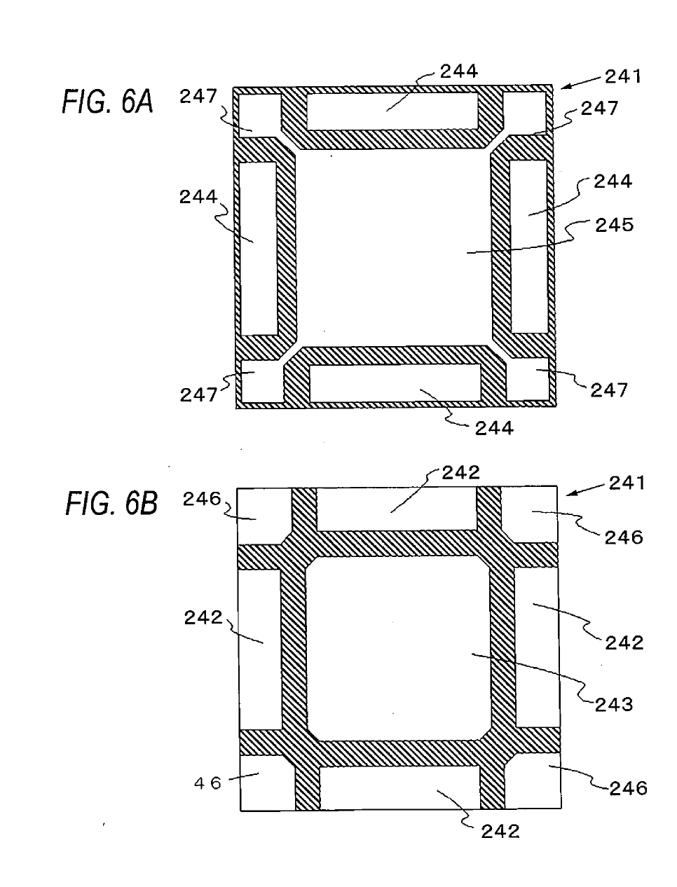

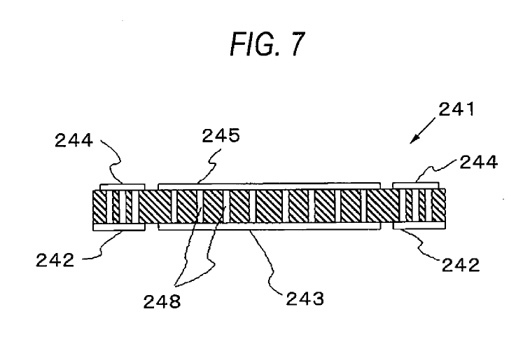

A mounting board on which the capacitor element used in the second embodiment is mounted will be described with reference to FIGS. 6 and 7. A mounting board 241 uses an insulating board such as a rectangular glass epoxy board as a base, and includes anode terminal portions 242 and a first cathode terminal portion 243 on a mounting surface thereof facing a wiring board on which a solid electrolytic capacitor is mounted. The mounting board includes anode conductors 244 and a cathode conductor 245 on the surface thereof on which a capacitor element is mounted. The anode conductors 244 and the cathode conductor 245 are connected to anode lead-out portions and a cathode lead-out portion of the capacitor element, respectively. Further, the mounting board makes the anode conductors 244 and the anode terminal portions 242, which are formed on the respective surfaces of the mounting board, be electrically conducted to each other, and makes the cathode conductor 245 and the first cathode terminal portion 243, which are formed on the respective surfaces of the mounting board, be electrically conducted to each other.

In more detail, as shown in FIG. 6A, a cathode conductor 245, which is joined to the cathode lead-out portion of the capacitor element, is formed at the central portion of the surface of the mounting board 241, on which the capacitor element is mounted, in a square shape. Four anode conductors 244 are disposed on four sides of the mounting board 241 so as to surround the outer periphery of the cathode conductor 245. Further, auxiliary conductors 247, which are electrically connected to the cathode conductor 245, are disposed at four corners of the mounting board 241. Meanwhile, as shown in FIG. 6B, a first cathode terminal portion 243, of which the size is substantially the same as that of the anode conductor 244, is formed at the central portion of the mounting surface of the mounting board 241, and four anode terminal portions 242 are disposed on the four sides of the mounting board 241 so as to surround the outer periphery of the first cathode terminal portion 243. Furthermore, second cathode terminal portions 246 are disposed at four corners of the mounting surface of the mounting board 241 so as to be adjacent to the anode terminal portions 242. As shown in FIG. 7, the anode conductors 244, the anode terminal portions 242, the cathode conductor 245, the first cathode terminal portion 243, the auxiliary conductors 247, and the second cathode terminal portions 246, which are formed on both surfaces of the mounting board 241, are electrically joined to each other through conductors 248, which penetrate the surface and back of the mounting board, such as via holes or through holes that are formed substantially perpendicular to the board surface of the mounting board 241.

The anode conductors 244 and the cathode conductor 245, which are disposed on the surface of the mounting board 241 on which the capacitor element is mounted, are conductors that correspond to the anode lead-out portions and the cathode lead-out portion, respectively. The anode conductors 244 and the cathode conductor 245 have a mountable size and disposition so as to correspond to the shape of the capacitor element. When a cruciform capacitor element, of which the shape in a top view is suitable as the shape of the above-mentioned capacitor element, is used, the cathode conductor 245 corresponding to the cathode lead-out portion of the capacitor element occupies the largest area among the conductors formed on the mounting board 241. Further, if the first cathode terminal portion 243, which is connected to the cathode conductor 245 by through holes or the like, is formed so as to occupy the same area as the area occupied by the cathode conductor 245, the first cathode terminal portion 243 is disposed so that a distance between the first cathode terminal portion and the cathode lead-out portion of the capacitor element is shortest through the cathode conductor 245 and the through holes. Accordingly, it is possible to shorten the current path that is a factor reducing ESL. Accordingly, even on the mounting surface of the mounting board 241, the area occupied by the first cathode terminal portion 243 is largest as compared to the areas occupied by the anode terminal portions 242 and the second cathode terminal portions 246. Further, the increase of the area occupied by the first cathode terminal portion 243 also means the increase of current capacity. Accordingly, it is possible to make a large current flow when electric charge accumulated by the capacitor element is output, and it is possible to rapidly restore the state of an instant voltage drop by supplying electric charge, which is required during the transient response, by a large current.

An insulating board having a thickness of about 200 μm is preferably used as the insulating board, which is the base of this mounting board, in terms of strength. However, an insulating board having a thickness of about 80 μm may be used as the insulating board that is the base of this mounting board. Further, it is sufficient that each of the anode terminal portions, the first cathode terminal portion, the second cathode terminal portions, and the conductors formed on the insulating board can be soldered to a material having low electrical resistance, and it is preferable that copper or a conductor formed by plating nickel with gold be used as the conductor. The electrode and the conductor may be formed on one surface so as to have a thickness in the range of 3 to 5 μm. Furthermore, the anode terminal portions, the cathode terminal portion, and the conductors of the mounting board 241, the through holes that electrically join the terminal portions and the conductors, and the like may be formed by a method of forming a double-sided wiring board that is frequently used as a printed wiring board. In this case, the dispositions, the inner diameters, and the like of the through holes may be set arbitrarily.

Meanwhile, it is preferable that the first cathode terminal portion 243 and the second cathode terminal portions 246 be insulated on the mounting surface of the mounting board 241 by a resist layer. If a conductive pattern, which connects the first cathode terminal portion 243 to the second cathode terminal portions 246, is exposed to the mounting surface of the mounting board 241, a distance between the conductive pattern, which connects the first cathode terminal portion 243 to the second cathode terminal portions 246, and the anode terminal portion 242 is small. Accordingly, when soldering is performed on the mounting surface, a solder bridge is formed. For this reason, there is a concern that a short circuit occurs. Therefore, when a conductive pattern, which connects the first cathode terminal portion 243 to the second cathode terminal portions 246, is formed on the mounting surface of the mounting board 241, it is preferable that at least the conductive pattern be coated with a resist layer.

In addition, in order to electrically connect the first cathode terminal portion 243 to the second cathode terminal portions 246, it is most preferable to connect the cathode conductor 245 to the auxiliary conductors 247 by a conductive pattern on the surface of the mounting board 241 on which the capacitor element is mounted and to connect the auxiliary conductors 247 to the second cathode terminal portions 246 by through holes or the like. Even if the conductive pattern is formed on any one of the mounting surface and the surface on which the capacitor element is mounted, the characteristics of the solid electrolytic capacitor are not seriously affected. However, the reason why the conductive pattern is formed on the surface of the mounting board on which the capacitor element is mounted is that the conductive pattern is electromagnetically coupled with a conductive pattern formed on the wiring board or the like on which the solid electrolytic capacitor is mounted and may generate noise if the conductive pattern is formed on the mounting surface.

Further, it is preferable that the anode terminal portions 242 and the second cathode terminal portions 246 of the mounting board 241 be formed on the mounting board up to the end portions of the mounting surface of the mounting board 241. If the anode terminal portions 242 and the second cathode terminal portions 246 are formed up to the end portions of the mounting surface of the mounting board 241, solder fillets are formed between a conductive pattern of a wiring board or the like and the anode terminal portions 242 and the second cathode terminal portions 246 when the solid electrolytic capacitor is mounted on the wiring board or the like by soldering. Accordingly, visibility related to whether the second cathode terminal portions are reliably connected by soldering is improved. Furthermore, if the anode terminal portions 242 and the second cathode terminal portions 246 are formed on the mounting board from the mounting surface of the mounting board 241 up to the side surfaces of the mounting board, large solder fillets are formed. Accordingly, this is preferable.

In this mounting board, first, it is possible to achieve the distances from the anode lead-out portion and the cathode lead-out portion of the capacitor element to the anode terminal portions and the first cathode terminal portion of the mounting board, which are outlets of current, by a distance corresponding to only the thickness of the mounting board, and to shorten the current path. In particular, it is preferable that the thickness of the mounting board be about 200 μm, but a mounting board having a thickness of about 80 μm may be manufactured. Accordingly, it is possible to extremely shorten a distance between the first cathode terminal portion and the cathode lead-out portion of the capacitor element as compared to a case where a capacitor element is mounted on a lead frame and is molded with a resin. Second, since the anode terminal portions of the mounting board are disposed so as to be surrounded by the first cathode terminal portion and the second cathode terminal portions in three directions, an effect for canceling a magnetic field induced by the anodes and the cathode is large. Third, it is possible to divide a current path into four current paths and to make a practical ESL be 1/4 by forming the anode terminal portions at four positions. It is possible to reduce ESL of the solid electrolytic capacitor together with these two ESL reduction effects.

That is, the solid electrolytic capacitor of the invention comprehensively improves an ESL reduction effect by using all of a method of extremely shortening the length of a current path that is a first element technique for achieving low ESL; a method of canceling a magnetic field, which is formed by a current path, by a magnetic field formed by another current path that is a second element technique; and a method of making practical ESL be 1/n by dividing a current path into n current paths that is a third element technique.

In addition, since the second cathode terminal portions, which are equivalent to the first cathode terminal portion in terms of an electric potential, are formed at four corners of the mounting surface of the mounting board 241, it may also be possible to increase the degree of freedom in the electrical conduction between the mounting board and a GND line of a wiring board and the like to be mounted. Further, in the solid electrolytic capacitor having a five-terminal structure in the related art, it was difficult to visually check whether the first cathode terminal portion is reliably soldered. However, since the second cathode terminal portions 246 are formed at four corners and the second cathode terminal portions 246 are formed on the mounting board up to the end portions of the mounting board 241, solder fillets are formed between a conductive pattern or the like of a wiring board to be mounted and the second cathode terminal portions 246. Accordingly, visibility related to whether the cathode terminal portions are reliably connected by soldering is improved.

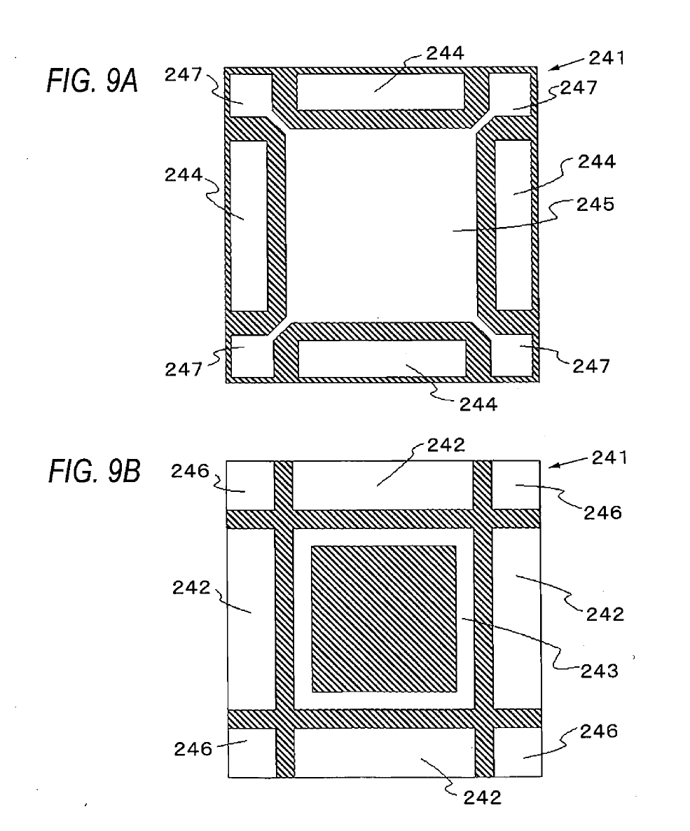

Moreover, as shown in a modification of FIG. 9, a first cathode terminal portion formed on the mounting board 241 does not have a pattern of which the entire surface is exposed and may be formed in a so-called hollow square shape where a conductive pattern is not formed at a central portion of the first cathode terminal portion 243 formed in a square shape and the central portion is an insulating area. If the first cathode terminal portion 243 is formed in the hollow square shape as described above, the current path of the first cathode terminal portion 243 becomes narrow and current is concentrated on the first cathode terminal portion. In addition, since the first cathode terminal portion on which current is concentrated is disposed close to the anode terminal portions 242, it is possible to further improve an effect for canceling an induced magnetic field and to obtain a solid electrolytic capacitor of which a comprehensive ESL reduction effect is further improved. In order to form the first cathode terminal portion 243, it is possible to make a central portion be an insulating area by forming a conductive pattern on the entire first cathode terminal portion 243 and coating the central portion of the first cathode terminal portion with a resist layer, without forming a conductive pattern in advance.

If the outer periphery area of the first cathode terminal portion 243 is formed at an area of which the size is substantially the same as the size of the cathode lead-out portion of the capacitor element even when the first cathode terminal portion 243 is formed in the so-called hollow square shape, the anodes and the cathode are disposed closest to each other and an effect for canceling an induced magnetic field is significantly preferable.

Meanwhile, in the characteristics as a single solid electrolytic capacitor, it is preferable that the first cathode terminal portion be formed in the above-mentioned hollow square shape. However, the shape of the first cathode terminal portion may be arbitrarily changed according to the disposition of a pattern of a board on which the solid electrolytic capacitor is mounted, the disposition of terminals of an IC to which power is supplied by the solid electrolytic capacitor, or the amount of power required. For example, in FIG. 6, the shape of the first cathode terminal portion 243 is not a complete square shape but an octagonal shape that is formed by cutting out the corners of a square shape.

Next, a process for mounting the capacitor element on the mounting board will be described. Here, there is provided an example where the same capacitor element 220 as the above-mentioned capacitor element 120, which is used in the first embodiment and shown in FIG. 2, is used.

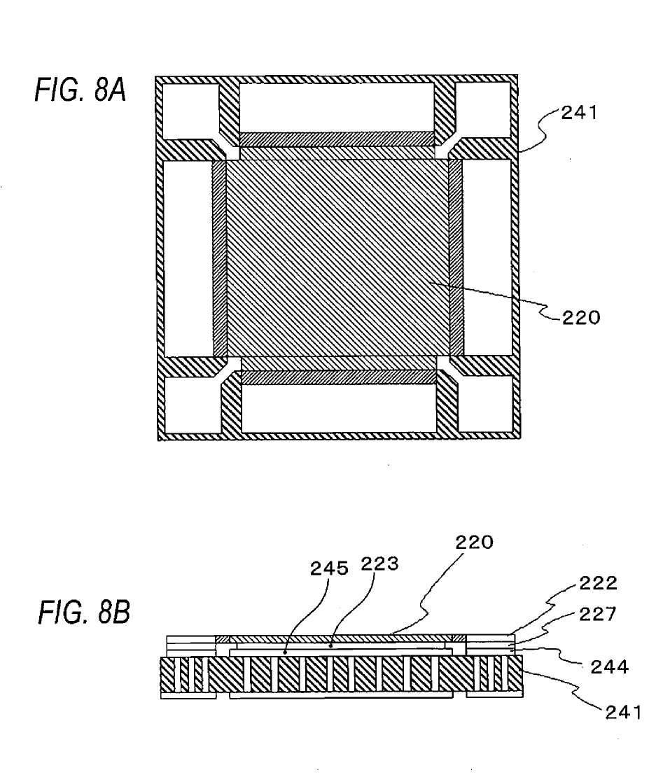

As shown in FIG. 8, a capacitor element 220 is mounted on the mounting board 241 and a cathode lead-out portion 223 of the capacitor element 220 and a cathode conductor 245 of the mounting board are joined to each other by a conductive adhesive material. Further, anode lead-out portions 222 of the capacitor element 220 are connected to anode conductors 244. In this case, the anode lead-out portion 222 of the capacitor element 220 is made of aluminum, has poor wettability between itself and a silver paste and the like, and may be difficult to adhere to the silver paste. In such a case, it is preferable that a connecting member 227 made of a copper material or the like be connected to the anode lead-out portion 222 of the capacitor element 220 by laser welding, ultrasonic welding, or the like and the connecting member 227 be joined to the anode conductor 244 of the mounting board 241 by a conductive adhesive material such as a silver paste.

Further, the number of capacitor elements mounted on the mounting board 241 is not limited to one. If large capacitance is required, it is possible to achieve the required capacitance by stacking more capacitor elements.

Furthermore, for the purpose of the mechanical protection of the capacitor element mounted on the mounting board or the blocking of the capacitor element from external air, packaging is performed by molding that is performed using a packaging resin. Meanwhile, packaging may be performed by attaching a case, which is made of a resin, to a board.

### Third Embodiment

Next, a third embodiment of the invention will be described. The same capacitor element pieces and capacitor element, which are formed by stacking the capacitor element pieces, as those of the first embodiment are used in the third embodiment.

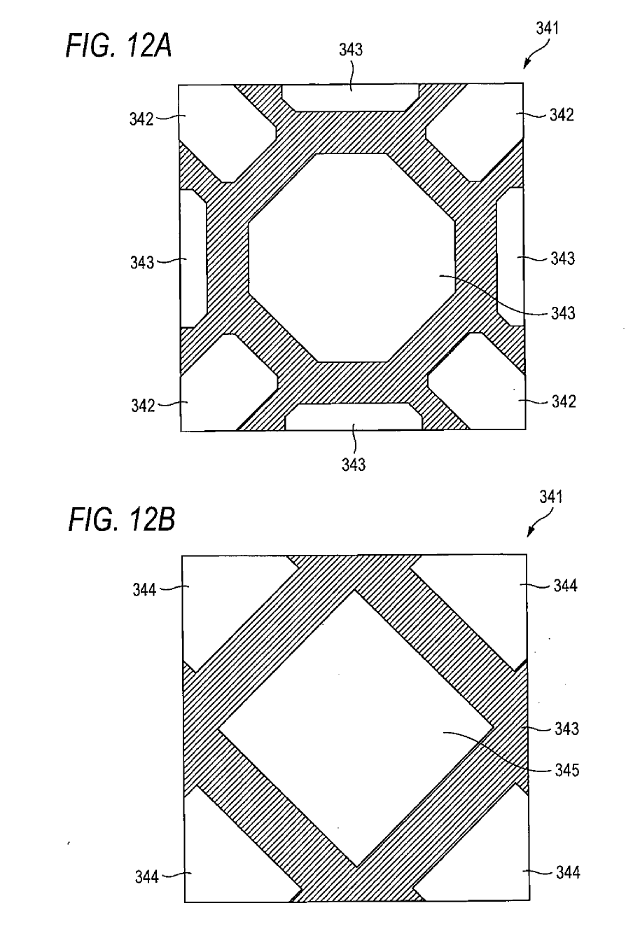

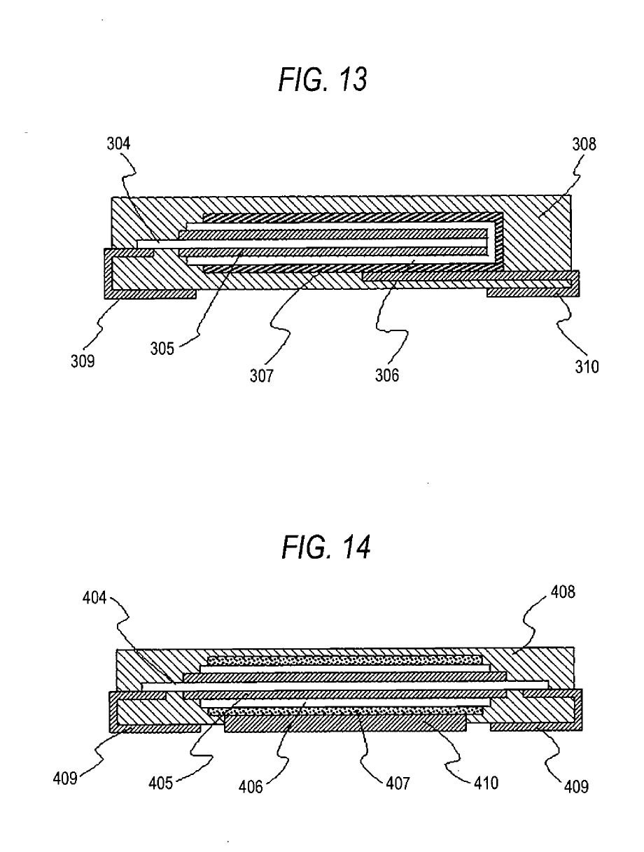

A mounting board on which the capacitor element used in the third embodiment is mounted will be described with reference to FIG. 12. A mounting board 341 uses an insulating board such as a rectangular glass epoxy board as a base, and includes anode terminal portions 342 and a cathode terminal portion 343 on the lower surface thereof. The mounting board includes anode conductors 344 and a cathode conductor 345 on the upper surface thereof. The anode conductors 344 and the cathode conductor 345 are connected to anode lead-out portions and a cathode lead-out portion of the capacitor element, respectively. Further, the mounting board makes the anode conductors 344 and the anode terminal portions 342, which are formed on the upper and lower surfaces of the mounting board, be electrically conducted to each other, and makes the cathode conductor 345 and the cathode terminal portion 343, which are formed on the upper and lower surfaces of the mounting board, be electrically conducted to each other.

The anode conductors 344 are disposed at four corners of a capacitor element mounting surface of the mounting board 341. Moreover, the cathode conductor 345, which is joined to the cathode lead-out portion of the capacitor element, is formed in a square shape at the central portion of the mounting board. Meanwhile, the anode terminal portions 342 are formed at four corners of a mounting surface of the mounting board 341, and the cathode terminal portion 343 is disposed at the central portion of the mounting surface. The anode conductors, the anode terminal portions, the cathode conductor, and the cathode terminal portion, which are formed on both surfaces of the mounting board 341, are electrically joined to each other through electrodes 348, which penetrate the surface and back of the mounting board, such as via holes or through holes.

Further, it is preferable that the cathode terminal portions 343 of the mounting board 341 be formed on the mounting board up to the end portions of the mounting surface of the mounting board 341. If the cathode terminal portions are formed on the mounting board up to the end portions of the mounting surface of the mounting board 341, solder fillets are formed between a conductive pattern of a printed board or the like and the anode terminal portions 342 and the cathode terminal portions 343 when the solid electrolytic capacitor is mounted on the printed board or the like by soldering. Accordingly, visibility related to whether the cathode terminal portions are reliably connected by soldering is improved. FIG. 12 shows an example where the cathode terminal portions 343 are formed on the mounting board up to the end portions of the mounting surface of the mounting board 341. The cathode terminal portions 343 formed at the end portions of the mounting board may be electrically connected to the cathode terminal portion 343 that is formed at the central portion of the mounting board, and may be formed so as to be separated on the mounting surface in appearance.

In this mounting board, the length of a diagonal line is about 1.4 times of the longitudinal dimension or the lateral dimension of the mounting board. If a transmission line is formed on the diagonal line, it is possible to form a transmission line of which the length is about 1.4 times of the length of a transmission that is formed parallel to a longitudinal or lateral direction of the mounting board. However, even though a transmission line is formed, the inlet and the outlet of the transmission line need to be electrically connected to each other. Considering a space where anode conductors for the connection of the transmission line are formed, the length of the transmission line becomes 1.1 to 1.3 times of the longitudinal dimension of the mounting board.

Further, if a distributed constant circuit is formed on the transmission line, it is possible to form a distributed constant circuit of which the length is 1.0 to 1.2 times of the length of a distributed constant circuit when a transmission line parallel to two sides of the mounting board is formed.

Here, the transmission line is formed between the anode lead-out portions of the capacitor element that face each other, and the distributed constant circuit is formed of a cathode layer (solid electrolyte layer) and a dielectric layer forming a capacity forming portion of the capacitor element. The length of the transmission line or the length of the distributed constant circuit is changed according to the shape or the width of the capacitor element, and may be arbitrarily designed in view of the length of the transmission line or capacitance to be required.

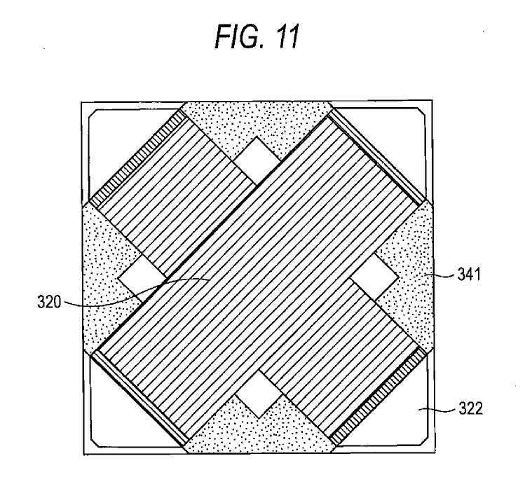

FIG. 11 is a view showing a modification where a mounting board having the same size is used and the length of a transmission line and the length of a distributed constant circuit are extremely long. If anode lead-out portions 322 of a capacitor element are formed in a substantially triangular shape and are formed so as to have the shapes corresponding to the corners of an element mounting surface of the mounting board, it is possible to further increase the length of a distributed constant circuit (the length of a cathode layer (solid electrolyte layer) of the capacitor element).

A glass epoxy board having a thickness of about 200 μm is preferably used as a glass epoxy board, which is a base of this mounting board, in terms of strength. However, a glass epoxy board having a thickness of about 80 μm may be used as the glass epoxy board that is the base of this mounting board. Further, it is sufficient that the conductor formed on the glass epoxy board can be soldered to a material having low electrical resistance, and it is preferable that copper or a conductor formed by plating nickel with gold be used as the conductor. The conductor may be formed on one surface so as to have a thickness in the range of 3 to 5 μm. Furthermore, the conductors and electrodes of the mounting board 341, the through holes that electrically join the conductors and electrodes, and the like may be formed by a method of forming a double-sided wiring board that is frequently used as a printed circuit board. In this case, the dispositions, the inner diameters, and the like of the through holes may be set arbitrarily.

As for a solid electrolytic capacitor using the mounting board, first, it is possible to achieve the distances from the anode lead-out portion and the cathode lead-out portion of the capacitor element to the anode terminal portion and the cathode terminal portion of the mounting board, which are outlets of current, by a distance corresponding to only the thickness of the mounting board, and to shorten the current path. In particular, it is preferable that the thickness of the mounting board be about 200 μm, but a mounting board having a thickness of about 80 μm may be manufactured. Accordingly, it is possible to extremely shorten a distance between the cathode terminal portion and the cathode lead-out portion of the capacitor element as compared to a solid electrolytic capacitor where a capacitor element is mounted on a lead frame and is molded with a resin. In addition, it is possible to divide a current path into four current paths and to make a practical ESL be 1/4 by forming the anode terminal portions at four positions.

That is, the solid electrolytic capacitor of the invention comprehensively improves an ESL reduction effect by using all of a method of extremely shortening the length of a current path and making effective ESL be 1/n by dividing a current path into n current paths.

In addition, since the cathode terminal portions 343 are formed at four sides of the mounting surface of the mounting board 341, it may also be possible to increase the degree of freedom in the electrical conduction between the mounting board and a GND line of a printed board and the like to be mounted. Further, in the solid electrolytic capacitor having a five-terminal structure in the related art, it was difficult to visually check whether the cathode terminal portions are reliably soldered. However, since the cathode terminal portions are formed at four sides, solder fillets are formed between a conductive pattern or the like of a printed board to be mounted and the cathode terminal portions 343. Accordingly, visibility related to whether the cathode terminal portions are reliably connected by soldering is improved.

Next, a process for mounting the capacitor element on the mounting board will be described. Here, there is provided an example where the same capacitor element 320 as the above-mentioned capacitor element 120, which is used in the first embodiment and shown in FIG. 2, is used.

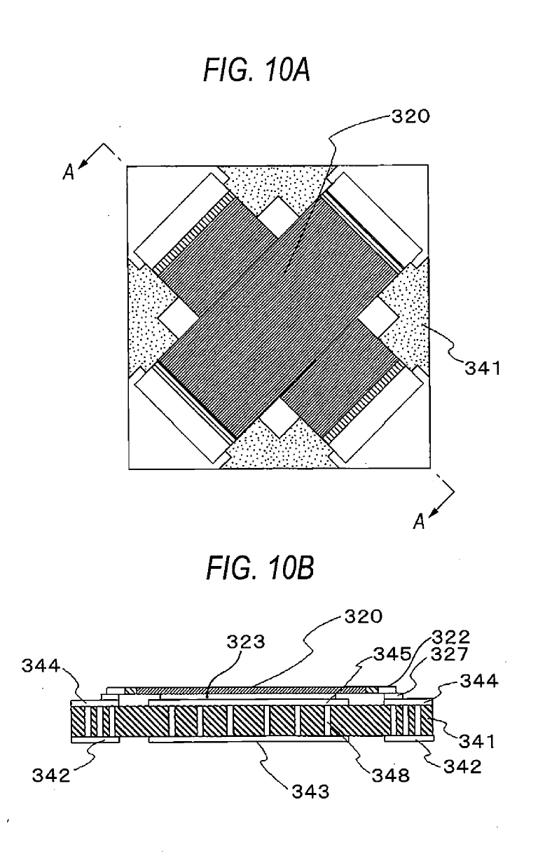

As shown in FIG. 10, a capacitor element 320 is mounted on the mounting board 341 and a cathode lead-out portion 323 of the capacitor element 320 and a cathode conductor 345 of the mounting board are joined to each other by a conductive adhesive material. Further, anode lead-out portions 322 of the capacitor element 320 are connected to anode conductors 344. In this case, the anode lead-out portion 322 of the capacitor element 320 is made of aluminum, has poor wettability between itself and a silver paste and the like, and may be difficult to adhere to the silver paste. In such a case, it is preferable that a connecting member 327 made of a copper material or the like be connected to the anode lead-out portion 322 of the capacitor element 320 by laser welding, ultrasonic welding, or the like and the connecting member 327 be joined to the anode conductor 344 of the mounting board 341 by a conductive adhesive material such as a silver paste.

Further, the number of capacitor elements mounted on the mounting board 341 is not limited to one. If large capacitance is required, it is possible to achieve the required capacitance by stacking more capacitor elements.

Furthermore, for the purpose of the mechanical protection of the capacitor element mounted on the mounting board or the blocking of the capacitor element from external air, packaging is performed by molding that is performed using a packaging resin. Meanwhile, packaging may be performed by attaching a case, which is made of a resin, to a board.

This application is based on Japanese Patent Application No. 2009-088318, filed on Mar. 31, 2009, Japanese Patent Application No. 2009-124737, filed on May 22, 2009, and Japanese Patent Application No. 2009-228751, filed on Sep. 30, 2009, the entire contents of which are incorporated herein by reference.

### REFERENCE SIGNS LIST

120: capacitor element
121: capacitor element piece
122: anode lead-out portion
123 cathode lead-out portion
124: separating layer
125: etching layer
127: connecting member
141: mounting board
142: anode terminal portion
143: cathode terminal portion
144: anode conductor
145: cathode conductor
148: through hole (electrode)
149: conductive material
220: capacitor element
222: anode lead-out portion
223: cathode lead-out portion
227: connecting member
241: mounting board
242: anode terminal portion
243: first cathode terminal portion
244: anode conductor
245: cathode conductor
246: second cathode terminal portion
247: auxiliary conductor
248: through hole (conductor)
320: capacitor element
322: anode lead-out portion
323: cathode lead-out portion
327: connecting member
341: mounting board
342: anode terminal portion
343: cathode terminal portion
344: anode conductor
345: cathode conductor
348: through hole (electrode)

1. A solid electrolytic capacitor comprising:
a capacitor element that includes capacitor element pieces, both ends of an anode body of each of the capacitor element pieces forming anode lead-out portions and both surfaces of a middle portion of the anode body forming cathode lead-out portions, and the capacitor element pieces being stacked so that the cathode lead-out portions overlap with each other and the anode lead-out portions are substantially orthogonal to each other.

2. The solid electrolytic capacitor according to claim 1,
wherein the cathode lead-out portions of the side surfaces of the stacked capacitor element pieces are connected to each other by a conductive material.

3. A solid electrolytic capacitor including a capacitor element where both ends of an anode body form anode lead-out portions and a dielectric layer, a solid electrolyte layer, and a cathode lead-out portion are sequentially formed on the anode body,
wherein a first cathode terminal portion is disposed at the center of a mounting surface facing a wiring board, anode terminal portions are disposed around the first cathode terminal portion, and second cathode terminal portions are disposed adjacent to the anode terminal portions.

4. A solid electrolytic capacitor comprising:
a capacitor element where both ends of an anode body form anode lead-out portions and a dielectric layer, a solid electrolyte layer, and a cathode lead-out portion are sequentially formed on the anode body; and
a mounting board that includes a surface on which the capacitor element is mounted and a mounting surface facing a wiring board, conductors, which correspond to the anode lead-out portions and the cathode lead-out portion of the capacitor element, respectively, being formed on the surface on which the capacitor element is mounted, anode terminal portions and a cathode terminal portion being formed on the mounting surface facing the wiring board, and the conductors penetrating the wiring board and being electrically connected to the anode terminal portions and the cathode terminal portion,
wherein a first cathode terminal portion is disposed at the center of the mounting surface of the mounting board, the anode terminal portions are disposed around the first cathode terminal portion, that is, on four sides of the mounting surface of the mounting board, and second cathode terminal portions are disposed at four corners of the mounting surface of the mounting board so as to be adjacent to the anode terminal portions.

5. The solid electrolytic capacitor according to claim 3,
wherein the first cathode terminal portion is formed at an area of which the size is substantially the same as the size of the cathode lead-out portion of the capacitor element and corresponds to an area larger than the anode terminal portions and the second cathode terminal portions.

6. The solid electrolytic capacitor according to claim 3,
wherein the first cathode terminal portion is disposed at an area that is a central portion of the mounting surface of the mounting board and close to the respective anode terminal portions, and an insulating area is formed at a central portion of the mounting surface.

7. A solid electrolytic capacitor including a capacitor element and a quadrangular mounting board, a mounting surface, which is surface-mounted on a printed board, being formed on one surface of the mounting board and an element mounting surface on which the capacitor element is mounted being formed on the other surface of the mounting board,
wherein the mounting board includes anode terminal portions that are disposed at four corners of the mounting surface of the element mounting surface, a cathode terminal portion that is disposed at a central portion of the element mounting surface, anode conductors that are electrically conducted to the anode terminal portions and disposed at four corners of the element mounting surface, and a cathode conductor that is electrically conducted to the cathode terminal portion and disposed at a central portion of the element mounting surface,
the capacitor element includes a capacity forming portion, a cathode layer, and a cathode lead-out portion that are sequentially stacked on a central portion of a conductive body, and anode lead-out portions that are formed of four conductive bodies protruding from the periphery of the cathode lead-out portion, and
the anode lead-out portions of the capacitor element are connected to the anode conductors of the mounting board, the cathode lead-out portion of the capacitor element is connected to the cathode conductor, and transmission line structures are formed by the conductive bodies of the capacitor element that are positioned at opposite corners of the mounting board.

8. The solid electrolytic capacitor according to claim 7,
wherein the capacitor element is formed of a rectangular conductive body, and the anode lead-out portions are formed by stacking a plurality of capacitor element pieces, each of which protrudes from both ends of the cathode lead-out portion, in a cross shape.

9. The solid electrolytic capacitor according to claim 7,
wherein the capacitor element is formed of a cross-shaped conductive body and the anode lead-out portions protrude from the periphery of the cathode lead-out portion.
